(19) United States
(12) Patent Application Publication
(10) Pub. No.: US 2004/0028837 A1
(43) Pub. Date: Feb. 12, 2004

(54) Method and apparatus for plasma processing

(75) Inventor: Steven T. Fink, Mesa, AZ (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/463,854

(22) Filed: Jun. 18, 2003

Related U.S. Application Data
(60) Provisional application No. 60/391,927, filed on Jun. 28, 2002.

(51) Int. Cl. C23C 16/00; H05H 1/10; C23F 1/00

(52) U.S. Cl. 427/575; 427/571; 118/723 R; 118/723 E; 156/345.46; 156/345.47

(57) ABSTRACT

An apparatus for processing a workpiece with a plasma includes a plasma chamber having an interior processing space, a plasma generating assembly, a gas supply system communicated to the chamber and operable to supply one or more gasses to the processing space, and a vacuum system communicated to the chamber and operable to remove gas from the chamber. A magnet assembly having a plurality of magnets and being constructed and arranged to hold the plurality of magnets in a predetermined configuration is rotatably mounted within the chamber so that the plurality of magnets are positioned to impose a magnetic field on a plasma within the processing space.

This non-provisional application claims the benefit of U.S. Provisional Application No. 60/391,927, which was filed on Jun. 28, 2002, the content of which is incorporated in its entirety.

### FIELD OF THE INVENTION

The present invention relates to plasma processing apparatuses and more particularly to methods and apparatuses for imposing magnetic fields on plasma to alter or control plasma characteristics.

### BACKGROUND OF THE INVENTION

A plasma is a collection of charged particles and radicals that may be used to remove material from or deposit material on a workpiece. Plasma may be used, for example, to etch (i.e., remove) material from or to sputter (i.e., deposit) material on a semiconductor substrate during integrated circuit (IC) fabrication. A plasma may be formed in a plasma reactor by applying a radio frequency (RF) power signal to a process gas contained within a plasma chamber of the reactor to ionize and dissociate the gas particles. There are many types of plasma reactors. An RF source may be coupled to the plasma through a capacitance, through an inductance, or through both a capacitance and an inductance. Magnetic fields may be imposed on the plasma in a particular reactor during plasma processing of a workpiece for many reasons, including to alter plasma characteristics or to control the plasma processing of the workpiece.

For example, magnetic fields are sometimes used to contain the plasma within the chamber or to reduce plasma loss to the wall and electrode surfaces and to increase plasma density. Increasing plasma density may increase the number of plasma particles striking the workpiece which may decrease the time required to process a workpiece.

Magnetic fields imposed on the plasma may also be used to increase the uniformity of the distribution of plasma within the chamber. Non-uniform distribution of plasma within a plasma chamber may be undesirable because non-uniform distribution may result in non-uniform processing of the workpiece and may, in some situations, cause plasma-induced damage to the workpiece being processed.

### SUMMARY OF THE INVENTION

The present invention includes methods and apparatuses for utilizing magnetic fields to alter or control the condition of a plasma.

### BRIEF DESCRIPTION OF THE DRAWINGS

FIG. 1 is a schematic diagram of an illustrative embodiment of a plasma processing apparatus;

FIG. 2 is a cross-sectional view of a portion of a capacitively coupled plasma processing apparatus showing an illustrative embodiment of a magnet assembly mounted within a first electrode assembly thereof;

FIG. 3 is a perspective view of the magnet assembly of FIG. 2;

FIG. 4 is an exploded view of the magnet assembly of FIG. 3;

FIG. 5 is an enlarged view of a portion of the first electrode assembly of the apparatus of FIG. 2;

FIG. 6 is a cross-sectional view of a portion of a capacitively coupled plasma processing apparatus showing an illustrative embodiment of a magnet assembly mounted within an insulator structure thereof;

FIG. 7 is an enlarged view of a portion of the insulator structure of the apparatus of FIG. 6;

FIG. 8 is a cross-sectional view of a portion of a capacitively coupled plasma processing apparatus showing an illustrative embodiment of a magnet assembly mounted about the exterior of a chuck electrode assembly thereof;

FIG. 9 is an enlarged view of a portion of the chuck electrode assembly of the apparatus of FIG. 8;

FIG. 10 is a schematic view of a portion of a capacitively coupled plasma processing apparatus showing an illustrative embodiment of a magnet assembly mounted within the interior of a chuck electrode assembly thereof;

FIG. 11 is a cross-sectional view of a portion of the capacitively coupled plasma processing apparatus showing an illustrative embodiment of a magnet assembly mounted within the interior of a chuck electrode assembly thereof;

FIG. 12 is an enlarged view of a portion of the chuck electrode assembly of the apparatus of FIG. 11;

FIG. 13 is a cross-sectional view of an inductively coupled plasma processing apparatus showing an illustrative embodiment of a magnet assembly mounted within the interior of the reactor chamber thereof;

FIG. 14 is an enlarged view of a portion of the apparatus of FIG. 13; and

FIGS. 15-22 illustrate various arrangements and orientations that a plurality of magnets within a magnet assembly can assume.

### DETAILED DESCRIPTION OF THE INVENTION

The present invention is directed to the use of systems of magnets during plasma processing to alter or control the condition of a plasma. Each system of magnets may be embodied in a magnet assembly constructed according to principles of the present invention. Magnet assemblies constructed according to the principles of the present invention may be used in many different types of plasma reactors, including, for example, capacitively coupled plasma processors, inductively coupled plasma processors and transformer coupled processors.

Several illustrative embodiments of magnet assemblies are described below. The principles of the present invention and several illustrative embodiments of the invention are initially described utilizing a capacitively coupled plasma processor. Other illustrative embodiments of the invention are described utilizing other types of plasma reactors. Each example is given to facilitate the description of one or more embodiments of the invention. These examples are not intended, however, to limit the scope of the claimed invention to the embodiments described.

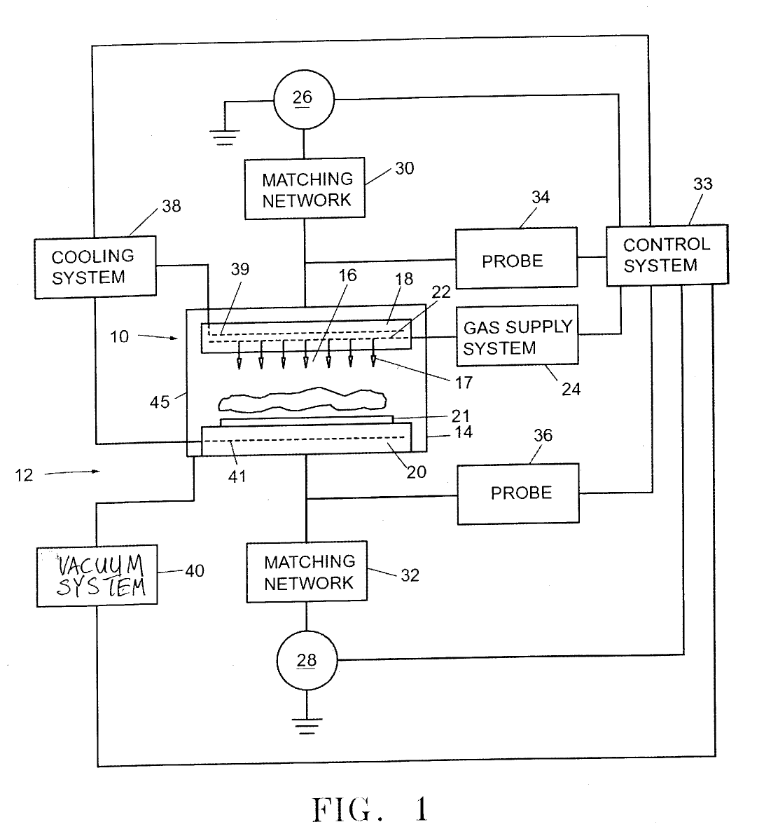

FIG. 1 shows schematically an example of a capacitively coupled plasma reactor 10 of a plasma apparatus 12. The reactor 10 includes a reaction chamber 14, which provides a processing space 16 in which a plasma may be contained and supported. One or more assemblies may be mounted within the chamber 14 in plasma generating relation to one another and/or to a process gas within the chamber 14. For example, a plasma generating assembly can comprise one or more electrodes, and/or one or more coils, and/or one or more antennas that can be used to generate a plasma from the process gas within the chamber 14.

In the example apparatus 12 of FIG. 1, first and second assemblies 18, 20 are mounted on opposite sides of the chamber 14. For example, the first assembly 18 may be a segmented electrode assembly or a single electrode assembly. To facilitate the description of the invention, the first electrode assembly 18 is in the form of a single showerhead-type electrode. Electrode assembly 18 may be operated to generate plasma within the chamber 14. The second assembly may be in the form of a chuck electrode assembly 20 that may be used to support a workpiece 21 for processing. Alternately, the second assembly 20 may be operated to generate plasma with chamber 14. The first electrode assembly 18 can include a passageway 22 (indicated by a broken line in FIG. 1) that is in pneumatic or fluidic communication with a gas supply system 24 through a gas supply line. A selected gas (or gasses) may be supplied to the electrode assembly 18 to purge the chamber 14, for example, or to serve as a process gas for plasma formation. The process gas is transmitted into the chamber 14 through a plurality of gas ports (not shown in FIG. 1) as indicated by the directional arrows 17.

The first and second electrode assemblies 18, 20 may be electrically communicated to respective RF power sources 26, 28 through associated matching networks 30, 32. Sources 26, 28 may be operated to provide RF signals to the associated electrode assembly 18, 20. The matching networks 30, 32 may be operated to increase the power transferred to the plasma by the respective electrode assemblies 18, 20. The matching networks 30, 32 may optionally be coupled to a control system 33. Alternatively, second electrode 20 may be coupled to ground. A probe 34, 36 may be coupled to a transmission line connecting a matching network 30, 32 to the associated electrode assembly 18, 20. Each probe 34, 36 may be operable to communicate information relating to an electrode parameter to the control system 33.

Each electrode assembly 18, 20 may be independently cooled by a fluid that circulates from a cooling system 38 through fluid passages generally designated 39, 41, respectively, in each electrode assembly 18, 20 and then back to the cooling system 38. The apparatus 12 further includes a vacuum system 40 in pneumatic or fluidic communication with the plasma reactor 10 through one or more vacuum lines.

The control system 33 is electrically communicated to various components of the apparatus 12 to monitor and/or control the same. The control system 33 is in electrical communication with and may be programmed to control the operation of the gas supply system 24, vacuum system 40, the cooling system 38, each RF power source 26, 28 the voltage probes 34, 36 and the matching networks 30, 32. The control system 33 may send control signals to and receive input signals (feedback signals, for example) from any or all of the apparatus components 24, 26, 28, 30, 32, 34, 36, 38 or 40. The control system 33 may monitor and control the plasma processing of the workpiece 21.

In an alternate embodiment, an insulator structure (not shown) may be mounted in the reaction chamber 14. For example, an upper portion of the insulator may be mounted to the first electrode assembly 18 and may extend downwardly therefrom toward the top surface of the chuck electrode assembly 20. The insulator may be a wall-like structure that is inwardly spaced from a chamber wall and surrounds at least a portion of the processing space 16. The construction and operation of an insulator are disclosed and described in U.S. patent application Ser. No. 60/331,253 filed Nov. 13, 2001, which application is hereby incorporated by reference in its entirety into the present application.

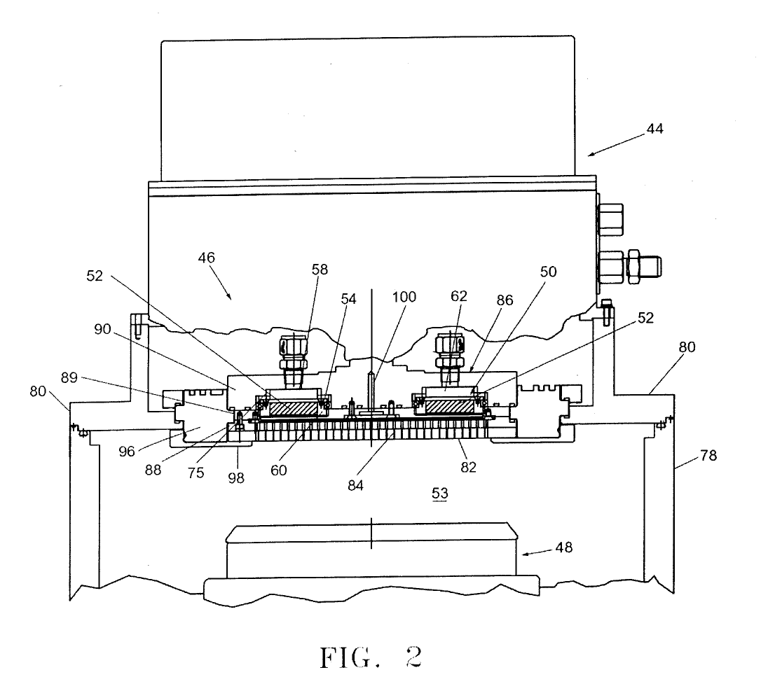

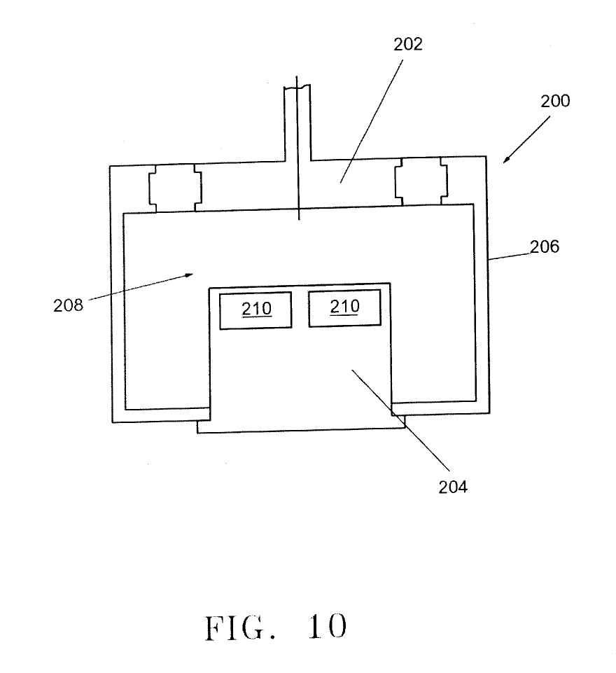

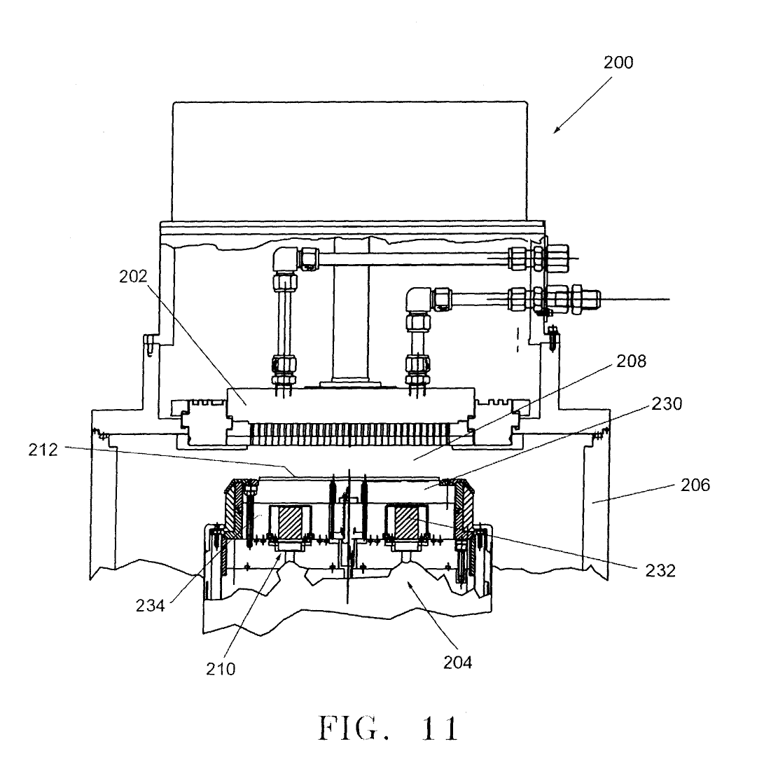

One or more magnet assemblies (not shown in FIG. 1) constructed according to principles of the present invention may be mounted within the chamber 14. A magnet assembly may be mounted, for example, within, on, around, above, or below the first electrode assembly 18, within, on, around, above, or below the second electrode assembly 20. Alternately, a magnet assembly may be mounted within, on the inside of, or on the outside of an insulator. The magnets of each magnet assembly may be operated to impose one or more magnetic fields on a plasma during a plasma processing operation to alter, affect and/or control the condition or conditions of the plasma. FIGS. 2-14 show several illustrative embodiments of magnet assemblies that can be mounted in various ways in various types of plasma reactors, each magnet assembly being constructed according to and illustrating one or more principles of the present invention.

FIG. 2, for example, shows an example of a capacitively coupled reactor 44 that may be incorporated into the plasma processing apparatus 12 of FIG. 1 generally in the same manner as the reactor 10. The plasma processing assembly 44 generally includes a first and second electrode assemblies 46, 48 and a magnet assembly 50 mounted for rotational movement with respect to the first electrode assembly 46. The first electrode assembly 46 may be operated to generate a plasma within the reaction chamber and the second electrode assembly 48 may function to support a workpiece (not shown) and may be operated to bias the workpiece to attract particles from the plasma to the workpiece.

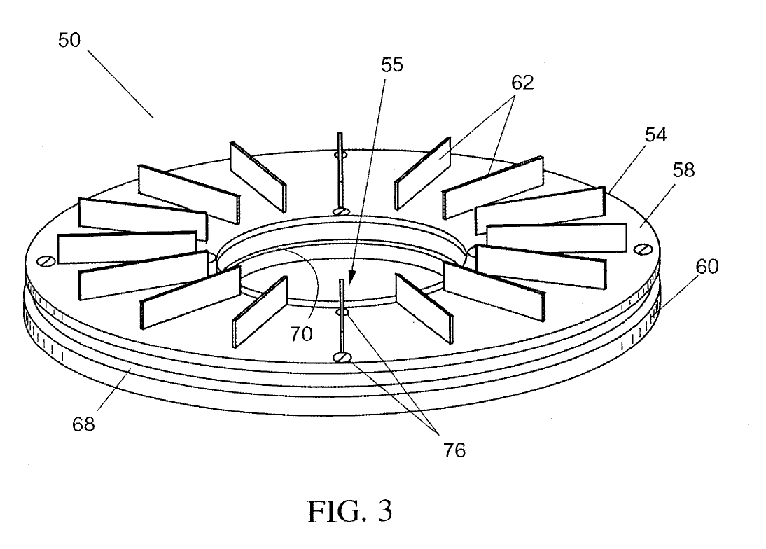

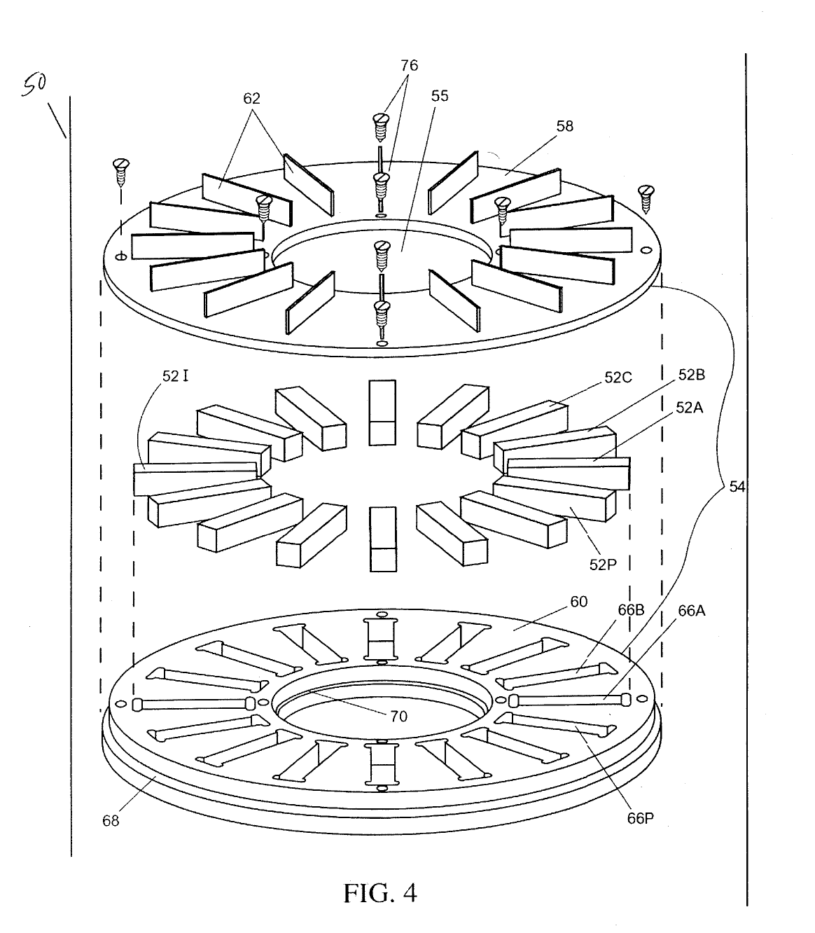

The magnet assembly 50 is shown in isolation in FIGS. 3 and 4. The magnet assembly 50 includes a plurality of magnets 52A-P and a magnet holding structure 54 that is constructed to hold the magnets 52A-P in one or more configurations and/or arrangements with respect to one another. The magnets 52 may be identical to one another (as shown) and each may be a permanent magnet. Each magnet 52 may be of any appropriate shape such as a curved shape (not shown) or a bar shape as shown. The magnets 52A-P may be constructed of any appropriate material such as ceramic materials, ferrite materials, rare earth materials, and alloy materials.

The magnet holding structure 54 is constructed to releasably hold the magnets 52A-P in a desired pattern and to allow each magnet 54 to be released from holding engagement with the magnet holding structure 54 to allow the position and/or orientation of each magnet 52 to be adjusted and to reengage each magnet 52 to hold each magnet 52 in a new position and/or orientation. For example, one or more spacers (not shown) can be used to position and/or orientate each magnet.

The magnet holding structure 54 is generally ring-shaped and has a central opening 55. The magnet holding structure 54 may be constructed of one or more materials such as a metal material (e.g., aluminum), a plastic material (e.g., Delrin) or a composite material. The material or materials selected to construct the magnet holding structure 54 may be a non-magnetic material and may be selected to facilitate the dissipation of heat from the magnets to, for example, a cooling fluid provided by the cooling system of the apparatus.

The magnets 52 are mounted on the magnet holding structure 54 in a predetermined configuration and the magnet holding assembly 54 is rotatably mounted in one or more locations in the reactor 44. When the magnet holding structure 54 is mounted in the reactor 44, the magnets 52 are positioned with respect to a processing space 53 to impose a magnetic field having a predetermined topology or topologies on a plasma (not shown) within the processing space 53. Rotation of the magnet holding structure 54 rotates the array of magnets 54A-P as a unit which causes the imposed magnetic field to rotate.

Accordingly, the magnet holding structure 54 generally includes structure to releasably hold each magnet 52 and structure constructed to cooperate with a source or supply of energy or force to rotate the magnet holding structure 54 and the array of magnets therein in a controlled manner during a plasma processing operation.

The illustrative magnet holding structure 54 is of two-piece construction and includes a ring-shaped first member 58 and a ring-shaped second member 60, each of which may be an integral structure. The first member 58 includes a plurality of integral vanes or impeller-type blades 62. The second member 60 includes a plurality of slots or recesses 66A-P, and a magnet 54A-P can be releasably held in each slot 66A-P. The second member 60 can also include circumferential exterior and interior recesses 68 and 70 that can be used as bearing guides. The first and second members 58, 60 are connected to one another by a series of threaded fasteners such as screws 76 to hold the magnets 54 within the slots 66.

Each magnet 52 includes North and South poles. These poles are at opposite ends of each illustrative magnet and define a magnetic axis of each magnet 52A-P. Each slot may be sized to allow angular and/or linear (in the radial direction of the magnet holding structure 54, for example) movement of each magnet 52A-P to allow each magnet 52 to assume multiple positions and/or orientations within the magnet holding structure 54.

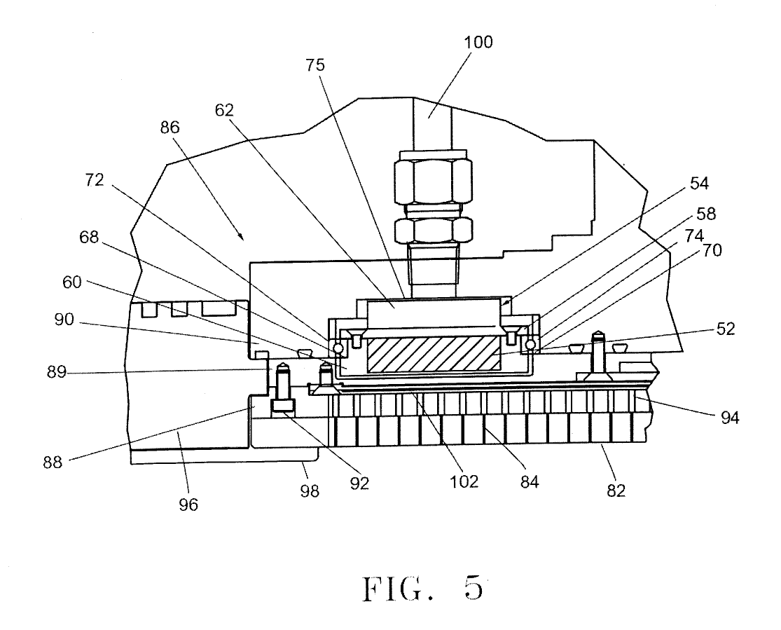

The magnet holding structure 54 is rotatably mounted in a manner considered below within the plasma reactor utilizing a pair of bearings 72, 74 (see FIG. 5, for example). Each bearing 72, 74 is mounted between a respective recess 68, 70 of the magnet holding structure 54 and an interior portion of the first electrode assembly 46. As considered below, the magnet holding structure 54 may be mounted within a fluid passageway 75 (illustrated as a ring-shaped passageway 75) formed within the first electrode assembly 46 through which a cooling fluid can flow. The passageway 75 is fluid communicated with the cooling system so that fluid from the cooling system circulates through the passageway 75. The fluid circulating through the passageway 75 impinges on one or more of the blades 62 and causes rotation of the magnet holding structure 54 with respect to the reactor 44. Thus, the blades engage the flowing fluid and the movement of the cooling fluid provides the energy to power the rotational movement of the magnet assembly and the plurality of magnets therein.

The magnets 52, blades 62 and slots 66 may be equally circumferentially spaced as shown in the example magnet holding structure 54. The magnets 52, the blades 62, the slots 66 are of approximately equal size and shape to one another. These spacings and sizes are not required by the invention, however. Each blade 62 is illustrated as a straight, relatively thin, wall-like structure that extends outwardly from the first member 58. Each blade 62 and each slot 66 is elongated and is approximately radially aligned with an imaginary horizontal line extending radially outwardly from an imaginary vertically extending central rotational axis of the magnet assembly, but this is not required. For example, one or more of the blades 62 could be angled from radial alignment and/or one or more portions of each blade could be curved (i.e., non-straight) or both.

The manner in which the magnet holding structure 54 and the magnets 52 are mounted in the reactor 44 can be understood from FIGS. 2 and 5. The first and second electrode assemblies 46, 48 are mounted in spaced relation to one another within the reaction chamber 78 and on opposite sides of the processing space 53. The chamber 78 includes a plurality of wall portions 80 that may be constructed of a dielectric material or a non-magnetic metal material such as aluminum. The first electrode assembly 46 in this example is a generally cylindrical structure and includes a plurality of sub-components.

The first electrode assembly 46 includes an outer electrode structure 82 that includes a plurality of gas outlet ports 84. The outer electrode structure 82 may be constructed of silicon. The first electrode assembly 46 further includes an inner electrode structure 86 that is comprised of first, second and third electrode members 88, 89, 90. The electrode members 88, 89, 90 may each be constructed of a metal material such as aluminum and may be physically and electrically connected to one another. The inner electrode structure 86 may be in electrical communication with a source of RF power (not shown).

The electrode members 88, 89, 90 may be connected to one another by threaded fasteners 92 of various sizes as shown. The first electrode member 88 is a cylindrical, plate-like structure that includes a plurality of gas outlet ports 94. The outer electrode structure 82 is mounted in covering relation to the inner electrode structure 86 by threaded fasteners (not shown) to cover and protect the inner electrode structure 86 by, for example, reducing deposition of plasma particles on or reducing etching of the inner electrode structure 86. The electrode structures 82, 86 are mounted on the chamber 78 by a ring-shaped insulator 96 which may be made of alumina or other appropriate dielectric material. The insulator 96 secures the electrode structures 82, 86 within the reaction chamber and electrically insulates the electrode structures 82, 86 from the walls 80 of the chamber 78.

A ring-shaped shield or cover 98, which may be constructed of a quartz or other appropriate material, is mounted on the insulator 96 in covering relation to the insulator 96 and in covering relation to a peripheral portion of the outer electrode structure 82.

A gas supply line 100 that is in communication with a gas supply system (not shown) is operable to carry a selected gas or gases to a gas passageway 102 between the first and second members 88, 89 of the inner electrode structure 86. Gas entering the passageway 102 is distributed into the processing space 53 of the reactor 44 through the gas processing ports 84, 94.

The inner electrode structure 86 includes the ring-shaped passageway 75. The magnet assembly 50 is mounted in the passageway 75 by the bearings 72 and 74. Alternatively, the magnet assembly 50 or an additional magnet assembly may be mounted within a passageway mounted in structure coupled to the insulator. The electrode structure 86 may be cooled during operation by circulating a fluid supplied from a cooling system through one or more fluid passageways in the electrode structure 86. The ring-shaped passageway 75 is in fluid communication with the fluid circulated by the cooling system so that a controlled supply of the fluid can be circulated through the passageway 75. As the fluid flows through the passageway 75, the circulating fluid imparts a fluid pressure on one or more of the blades 62 which causes the magnet holding structure 54 of the magnet assembly 50 to rotate within the passageway 75 with respect to the first electrode assembly 46 and the processing space 53.

The cooling fluid may be a dielectric fluid. A dielectric cooling fluid may be used, for example, in an instance in which the magnet assembly 50 and/or the cooling fluid are exposed to ambient RF or other electromagnetic energy. The construction of the blades 62 and the material selected to construct the magnet holding structure 54 may be chosen to facilitate heat transfer to the circulating fluid. For example, a metal such as aluminum may be selected to construct the magnet holding structure 54 because aluminum is a relatively good material for transferring heat. The blades may be constructed to be relatively thin and to provide a relatively high amount of surface area relative to their volume to facilitate heat exchange with the circulating fluid. Fluorinert is an example of a commercially available dielectric cooling fluid that may be used.

The shape and construction of the magnet holding structure 54 is influenced by a number of factors, including, for example, the construction of the first electrode assembly 46. Other constructions of the magnet assembly are contemplated as an alternative to a ring-shaped construction. The magnet holding structure 54 could be constructed to be essentially plate- or disk-shaped, for example, or, alternatively, to be wagon-wheel shape. When an alternate construction method is utilized, the magnet holding structure 54 may have either no central opening or, alternatively, a small central opening sized to accommodate structure required to rotatably mount the magnet holding structure such as a central rotational axis or bearing.

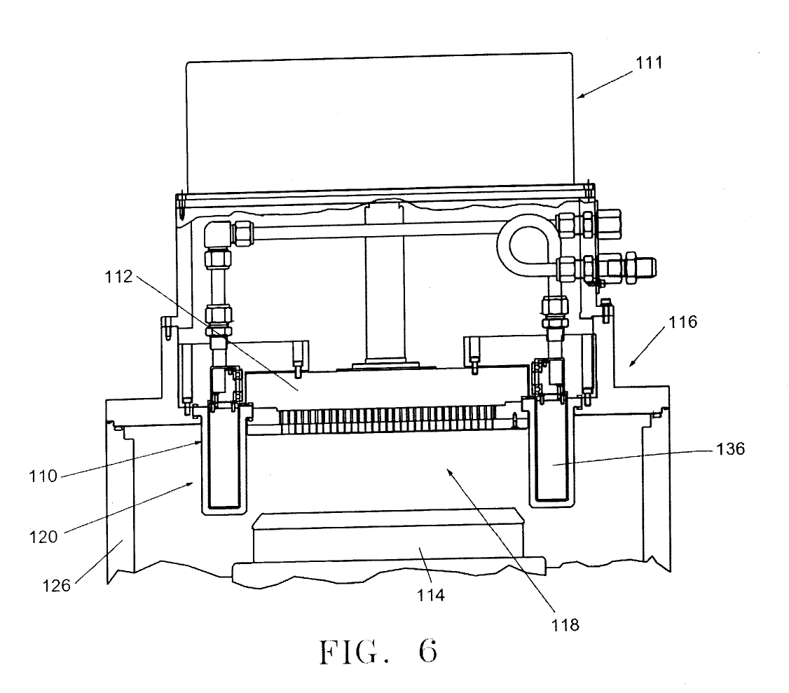

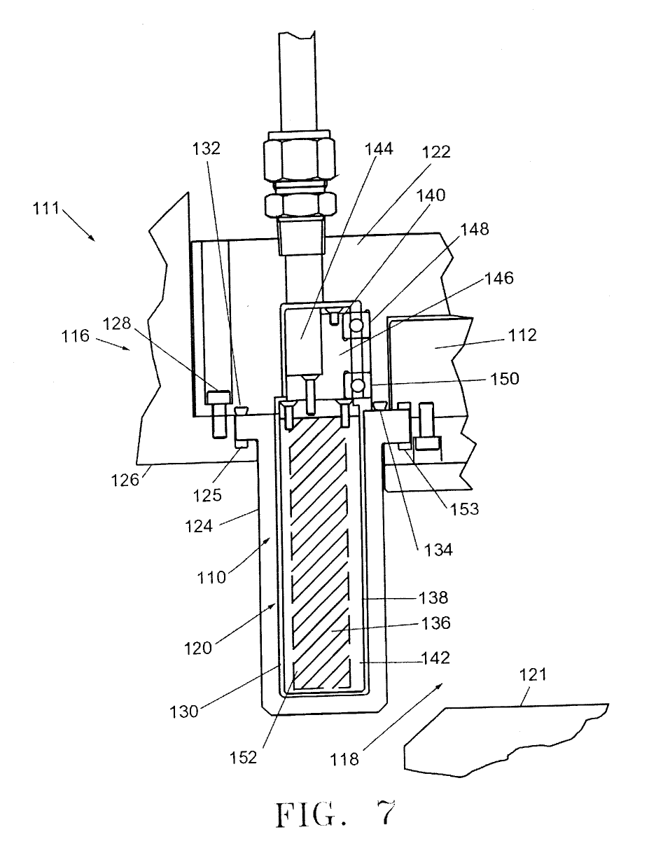

FIGS. 6 and 7 show another arrangement for mounting a magnet assembly 110 within a plasma reactor 111. The reactor 111 includes first and second electrode assemblies 112, 114, respectively, mounted and spaced relative to one another within the interior of a reaction chamber 116 to provide a processing space 118. The assemblies 112, 114 are mounted on opposite sides of the processing space 118. An insulator 120 is mounted to the upper electrode assembly 112, extends generally downwardly therefrom toward an upper surface 121 of the second (or chuck) electrode assembly 114, and generally surrounds the processing space 118.

The insulator 120 includes an upper member 122 and a lower insulating member 124 which are connected to one another by fasteners 128. The upper member 122 may be constructed of a dielectric material, a plastic such as Delrin, or a ceramic and is mounted generally between the processing space 118 and a wall portion 126 of the reaction chamber 116 utilizing various size fasteners 128. The lower insulating member 124 is mounted to the upper member 122 and extends generally downwardly therefrom. The illustrative lower insulating member 124 is generally ring-shaped, that is, in the shape of a hollow cylinder, and surrounds the processing space 118. The lower insulating member 124 may be constructed of an insulating material such as quartz, alumina, a ceramic or other appropriate material.

The lower insulating member 124 includes an interior passageway 130 in which the magnet assembly 110 is mounted. A pair of O-rings 132, 134 are disposed between the upper and lower insulating members 124 to seal the passageway 130 to assure that a fluid transmitted through the passageway 130 does not leak out of the passageway 130 into the interior of the chamber 116, and another set of O-rings 125, 153 are used to seal to the vacuum side. The magnet assembly 110 can be constructed to hold a desired number of magnets 136 in particular arrangements and/or orientations. For example, one or more spacers (not shown) can be used to position and/or orientate each magnet. The magnet assembly 110 includes a magnet holding structure 138 (FIG. 7) that is comprised of first and second members 140, 142, respectively, which may be connected to one another by fasteners (not shown). The first member 140 includes a plurality of vanes 144 and support structure 146 for engaging a pair of bearings 148, 150 for rotatably mounting the magnet assembly 110 within the passageway 130. The second member 142 includes a plurality of slots 152, each slot 152 being constructed to receive a magnet 136.

Each magnet 136 may be a permanent bar magnet (as shown in FIGS. 6 and 7), a curved magnet, or any other type of permanent magnet. As considered below, each bar magnet 136 may be mounted within the magnet assembly 110 such that its magnetic axis is generally vertical, generally horizontal, or such that the axis of each magnet 136 has any other desired orientation. In alternate embodiment, a bar magnet 136 can comprise one or more magnetic elements.

The passageway 130 can be in fluid communication with a source of cooling fluid (not shown in FIGS. 6 and 7) so that a cooling fluid circulates through the passageway 130 and imparts a force on one of more of the vanes 144 to rotate the magnet assembly 110 with respect to the processing space 118. The direction and rate of fluid flow of the fluid passing through the passageway 130 may be controlled to control the rotation (including the direction and speed) of the magnet assembly 110 within the passageway 130. Alternately, a motor may be used to control the rotation.

Although plasma reactor 111 is shown as being a capacitively coupled reactor, the magnet assembly 110 can be provided in any kind of reactor, such as, for example, an inductively coupled reactor or a transformer coupled reactor.

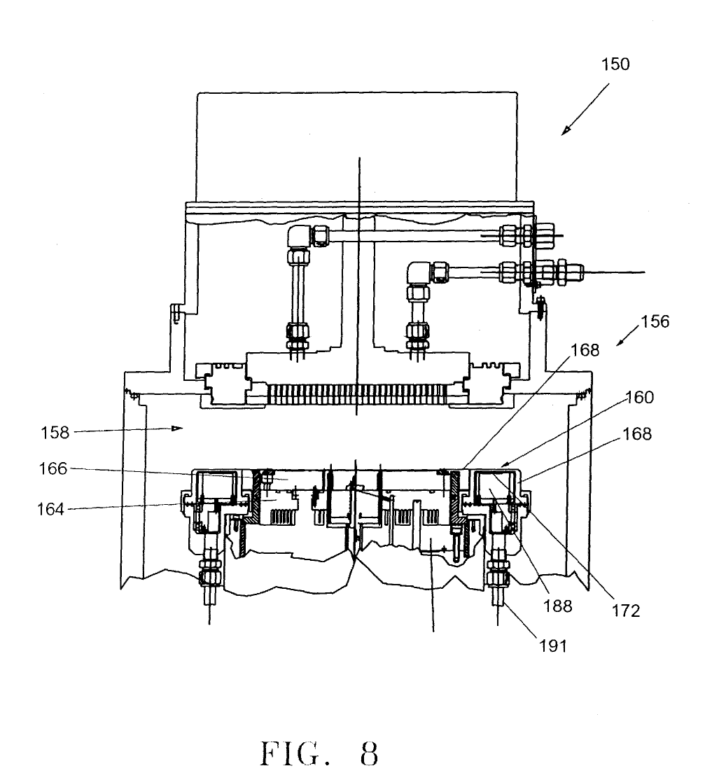

FIGS. 8-12 illustrate examples of magnet assemblies mounted on or within a chuck electrode assembly. FIGS. 8 and 9 show a plasma reactor 150 that includes a first electrode assembly 152 and a second (or chuck) electrode assembly 154 mounted within a reaction chamber 156 and a processing space 158 therebetween. A magnet assembly 160 is mounted about the periphery of the chuck electrode assembly 154. Although plasma reactor 150 is shown as being a capacitively coupled reactor, the magnetic assembly 160 can be provided in any kind of reactor, such as, for example, an inductively coupled reactor or a transformer coupled reactor.

The chuck electrode assembly 154 holds a workpiece or substrate (not shown) such as a silicon wafer for plasma processing. An inner electrode structure 164 is mounted within the chuck electrode assembly 154. The inner electrode structure 164 is a metal structure that may be coupled to an RF power source (not shown) or may be coupled to ground voltage. The electrode structure 164 may be RF biased during a plasma processing operation to form a plasma within the processing space 158 and/or to attract ions to the workpiece. An outer electrode structure 166, which may be in the form of a disk-shaped plate made of silicon or silicon carbide, may be mounted in covering relation over the inner electrode structure 164.

A focus ring structure 168 is mounted around the periphery of the workpiece supporting surface of the chuck electrode assembly 154. The focus ring structure 168 may comprise a ceramic, silicon, a silicon dioxide, or a composite material, and is generally constructed to surround the edge of the workpiece mounted on the chuck electrode assembly 154. The focus ring structure 168 may be made of the same material as the workpiece (as, for example, when the workpiece is a wafer of silicon dioxide) so that the focus ring structure 168 functions effectively to increase the size of the workpiece so that the plasma is more uniformly distributed over the wafer and so that edge effects are reduced.

A ring-shaped housing 170 is positioned about the periphery of the focus ring structure 168. The housing 170 may be made of a ceramic or other material and may form a portion of the magnet assembly 160. The housing 170 may also be made of a material suitable to reduce or eliminate edge effects on the workpiece during processing. The housing 170 includes a generally ring-shaped passageway 172 shaped to receive the magnet assembly 160 therein for rotational movement with respect thereto. The magnet assembly 160 is mounted within the passageway 172. The housing 170 includes first and second housing members 173, 175 that are secured to one another using fasteners 194, 195. A pair of O-rings 177, 197 are secured between the first and second housing members 173 to seal the passageway 172 to prevent fluid from leaking therefrom and to provide a vacuum seal.

The magnet assembly 160 includes first and second members 174, 176. The first member 174 is an integral structure that includes a plurality of vanes 178 and support structure 180 for rotatably mounting the magnet assembly 160 within the passageway 172 using bearings 182, 184. The second member 176 includes a plurality of slots 186, each of which holds a permanent magnet 188. The first and second members 174, 176 are secured to one another by a plurality of fasteners 190.

The passageway 172 can be in fluid communication with a source of cooling fluid (not shown in FIGS. 8 and 9) through one or more fluid lines 191 which may be connected to the housing so that a cooling fluid circulates through the passageway 172 and imparts a force on one of more of the vanes 178 to rotate the magnet assembly 160 with respect to the processing space 158. The direction and rate of fluid flow of the fluid passing through the passageway 172 may be controlled to control the rotation (including the direction and speed) of the magnet assembly 160 within the passageway 172. The fluid enters and exits the passageway 172 through fluid lines such as fluid line 191.

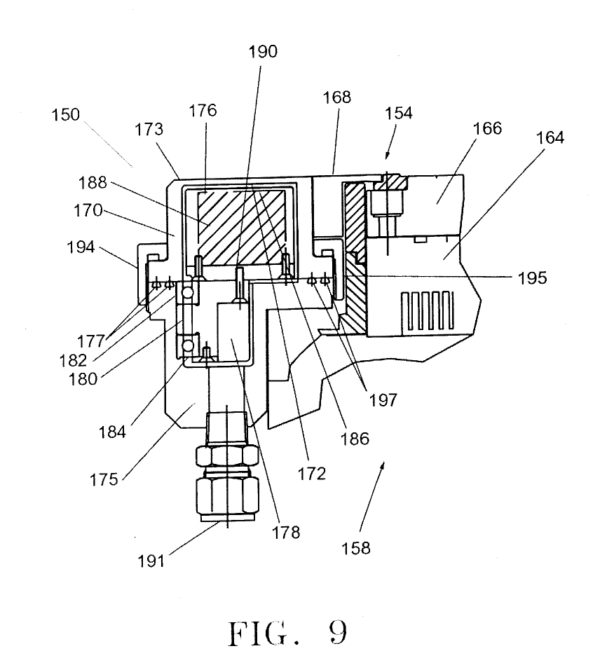

FIGS. 10-12 show a plasma reactor 200 that includes a first and second electrode assemblies 202, 204 mounted within a reaction chamber 206 and a processing space 208 therebetween. A magnet assembly 210 is mounted within the chuck electrode assembly 204. Although the plasma reactor 200 is shown as being a capacitively coupled reactor, the magnet assembly 210 can be provided in any kind of reactor, such as, for example, an inductively coupled reactor or a transformer coupled reactor.

The chuck electrode assembly 204 holds a workpiece or substrate 212 such as a silicon wafer for plasma processing. An inner electrode structure 214 which may be made of a metal material is mounted within the chuck electrode assembly 204 and may be coupled to an RF power source (not shown) through a capacitance (not shown) and a matching network (not shown) or may be coupled to ground. The electrode structure 214 is comprised of first and second electrode members 218, 220, respectively. The members 218, 220 are secured to one another by a plurality of fasteners 201. The electrode members 218, 220 cooperate when they are secured together to form a generally ring-shaped passageway 228. An outer electrode structure 230, which may be in the form of a disk-shaped plate made of silicon, silicon carbide, or a composite, may be mounted on the inner electrode structure 214.

The magnet assembly 210 can be constructed to hold a desired number of magnets 232 in a particular arrangements and/or orientations. The magnet assembly 210 includes a magnet holding structure 234 that is comprised of first and second members 236, 238, respectively, which may be connected to one another by fasteners 239. The first member 236 is an integral structure that includes a plurality of vanes 240. The magnet assembly 210 includes a pair of peripheral grooves 242, 243 for engaging, respectively, a pair of bearings 244, 246 for rotatably mounting the magnet assembly 210 within the passageway 228. The second member 238 includes a plurality of slots 248, each slot 248 being constructed to receive a magnet 232.

Each magnet 232 may be a permanent bar magnet or any other type of permanent magnet. Each bar magnet 232 may be mounted within the magnet assembly 210 so that its magnetic axis is generally vertical, generally horizontal, or so that each axis has any other desired orientation.

The passageway 228 can be in fluid communication with a source of cooling fluid (not shown) so that a cooling fluid imparts a force on one of more of the vanes 240 to rotate the magnet assembly 210 with respect to the processing space 208. The direction and rate of fluid flow of the fluid passing through the passageway 228 may be controlled to control the rotation (including the direction and speed) of the magnet assembly 210 within the passageway 228.

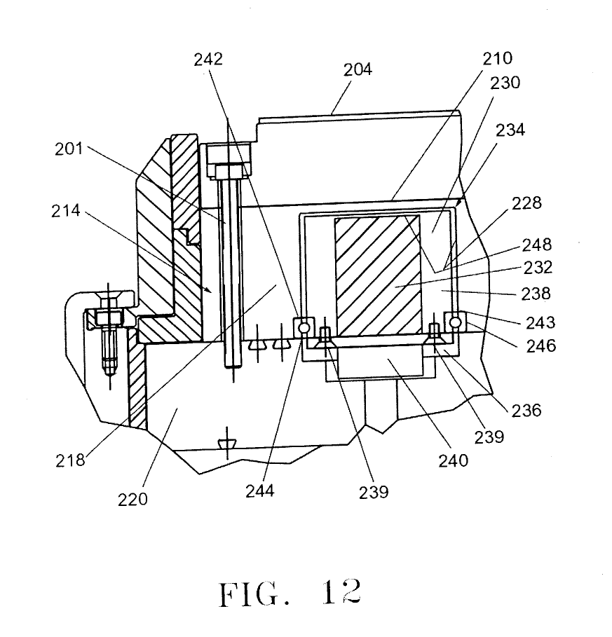

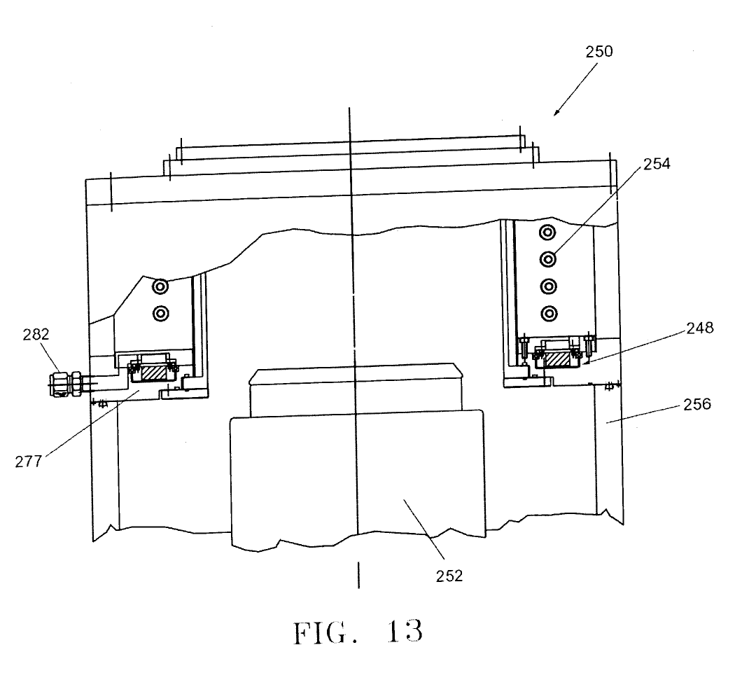

As mentioned, a magnet assembly constructed according to the principles of the present invention can be mounted within a capacitively coupled plasma reactor, within a transformer coupled plasma (TCP) reactor or in an inductively coupled plasma reactor. FIGS. 13 and 14 show an example of a magnet assembly 249 mounted within an inductively coupled reactor 250. The inductively coupled reactor 250 includes a chuck electrode assembly 252 and a coil structure 254 mounted within a reaction chamber 256. The coil structure 254 is in electrical communication with an electrical power source (not shown). The coil structure 254 can be energized by the power source to transfer energy to a processing gas or gasses injected into an upper part of the reaction chamber 256 to transform the gas into a plasma. The chuck electrode assembly 252 supports a workpiece (not shown) and the chuck electrode assembly 252 is in electrical communication with a power source (not shown) or ground voltage and may be constructed and operated to perform several functions, including biasing the workpiece to attract ions to the workpiece.

The magnet assembly 249 includes a magnet holding structure 258 that is comprised of first and second members 260, 262, respectively, which may be connected to one another by fasteners 264. The first member 260 is an integral structure that includes a plurality of vanes 266 and structure in the form of a pair of recesses 268, 270 for engaging a pair of bearings 272, 274 for rotatably mounting the magnet assembly 249 within a ring-shaped passageway 276 formed around the periphery of the inside of the chamber 256. The second member 262 includes a plurality of slots 278, each slot 278 being constructed to receive a magnet 280.

The passageway 276 may be formed by and within a housing 277 comprising a pair of members 279, 281 that are secured around the interior of the chamber 256. The housing 277 is mounted between the coil structure 254 and the chuck electrode assembly and generally surrounds the processing space of the reactor. The members 279, 281 may be constructed of a non-magnetic metal material and may be secured to one another by fasteners 283. The housing 277 may be secured within the chamber 256 or may form a portion of the chamber wall (as shown in FIG. 14, for example).

Each magnet 280 may be a permanent bar magnet or any other type of permanent magnet. The passageway 276 can be in fluid communication with a source of cooling fluid (not shown) through fluid lines such as fluid line 282 so that a cooling fluid flowing therein imparts a force on one of more of the vanes 266 to rotate the magnet assembly 249 with respect to the processing space above the chuck electrode assembly 252. The direction and rate of fluid flow of the fluid passing through the passageway 276 may be controlled to control the rotation (including the direction and speed) of the magnet assembly 249 within the passageway.

Of course, magnet assembly 249 may be employed in any kind of reactor, such as a capactively or transformer coupled reactor.

FIGS. 15-22 illustrate several examples of orientations and arrangements that a ring of magnets can assume within a particular appropriately constructed magnet assembly. Each illustration shows a ring-shaped array of sixteen equally circumferentially spaced permanent bar magnets. Each example array can be mounted in any of the locations within a reaction chamber (e.g., within the upper electrode assembly, within an insulator surrounding the processing space of the chamber, or within the chuck electrode assembly) described above. These examples are illustrative only and are not intended to limit the scope of the invention. For example, a greater or lesser number of magnets could be mounted within a particular magnet assembly, other spacings could be used and/or other types of magnets could be used.

FIG. 15 shows a top view of an arrangement of bar magnets 300A-P. The North and South poles of each magnetic 300A-P are indicated by a directional arrow. Each arrow indicates the direction of the magnetic axis of each magnet, the tail of each arrow indicating the location of the North pole and the arrowhead pointing toward the location of the South pole. The magnetic axis of each magnet 300A-P is parallel to the plane defined by the ring of magnets 300.

The North and South poles of magnets 300A and 300I are labeled with letters N and S, respectively. The axes of the magnets 300A and 300I are linearly aligned with one another. One or more generally magnetic field lines 310 that are generally straight extend between the magnets 300A and 300I and pass through the center of the ring formed by the magnet 300A-P. The orientation of the axis of each magnet 300A-P can be described with reference to this straight line 310. The incline of the axis of each magnet 300A-P with respect to the line S is 0°, 45°, 90°, 135°, 180°, 225°, 270°, 315°, 0°, 45°, 90°, 135°, 180°, 225°, 270°, and 315°, respectively. Thus, the angle of orientation changes in a stepwise manner by 45 degree increments in a counterclockwise direction starting from magnet 300A. The topology of the field lines generated by this arrangement of magnets 300 is shown in FIG. 15.

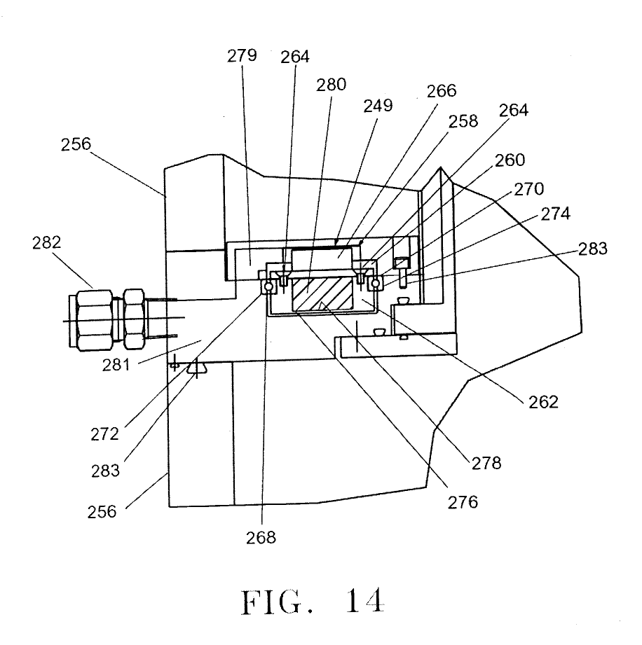

FIG. 16 shows a top view of another arrangement of bar magnets 302A-P. The North and South poles of each magnetic 302A-P are labeled with the letters N and S, respectively. The magnetic axis of each magnet 302A-P is parallel to the plane defined by the ring of magnets 302. The axis of each magnet 302A-P is radially aligned with approximately the center of the ring formed by the magnets 302. The magnets 302A-P are arranged so that the radially inner ends of the magnets 302A-P alternate in polarity N-S-N-S and so on. The field lines generated by this arrangement of magnets 300 are shown in FIG. 16. These field lines form a pattern or topology that is sometimes referred to as a magnetic bucket topology.

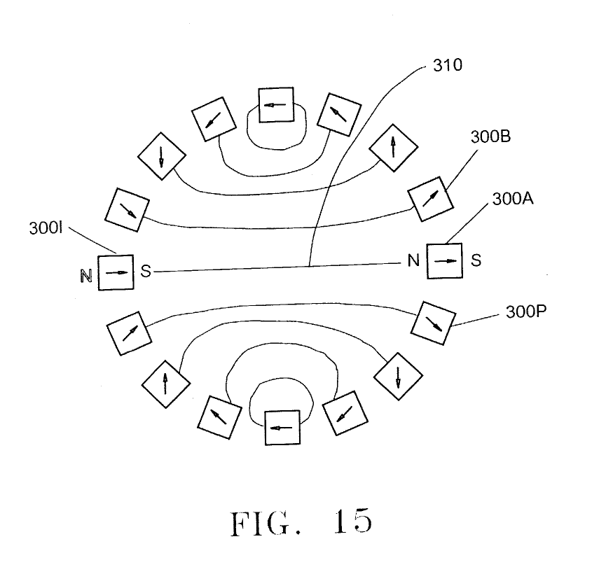

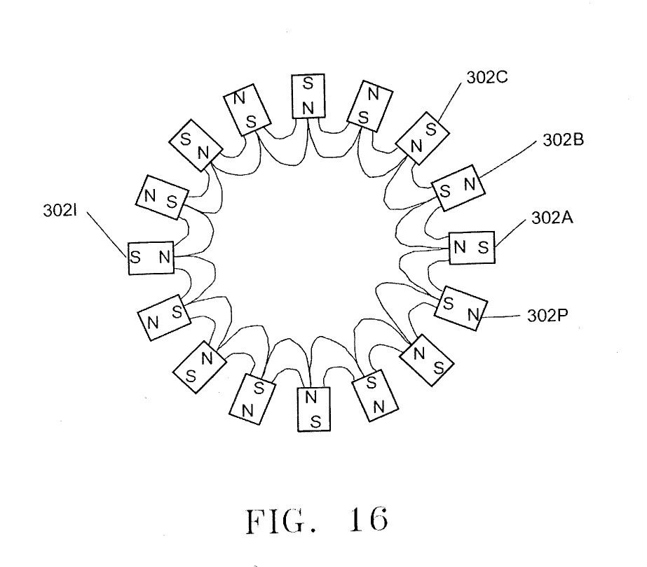

FIG. 17 shows a top view of another arrangement of bar magnets 304A-P. The arrangement of FIG. 17 is similar to the arrangement of FIG. 16 except that the North (or South) pole of each magnet 304A-P is positioned on the inside of the ring defined by the magnets 304. FIG. 18 shows in side view two magnets 304A and 304I that are positioned on opposite sides of the ring to illustrate the magnetic field line topology generated by this arrangement of magnets 304.

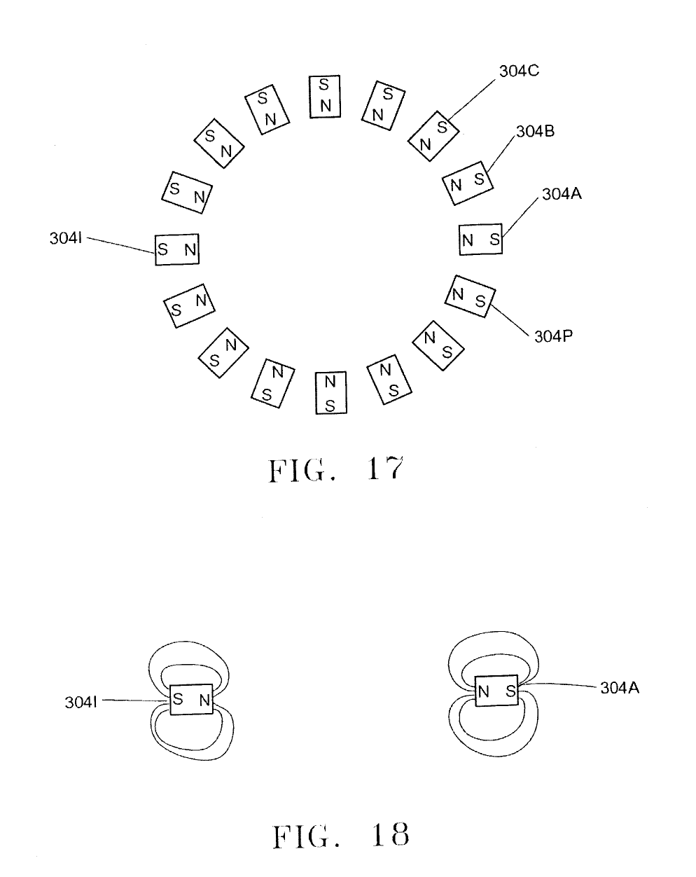

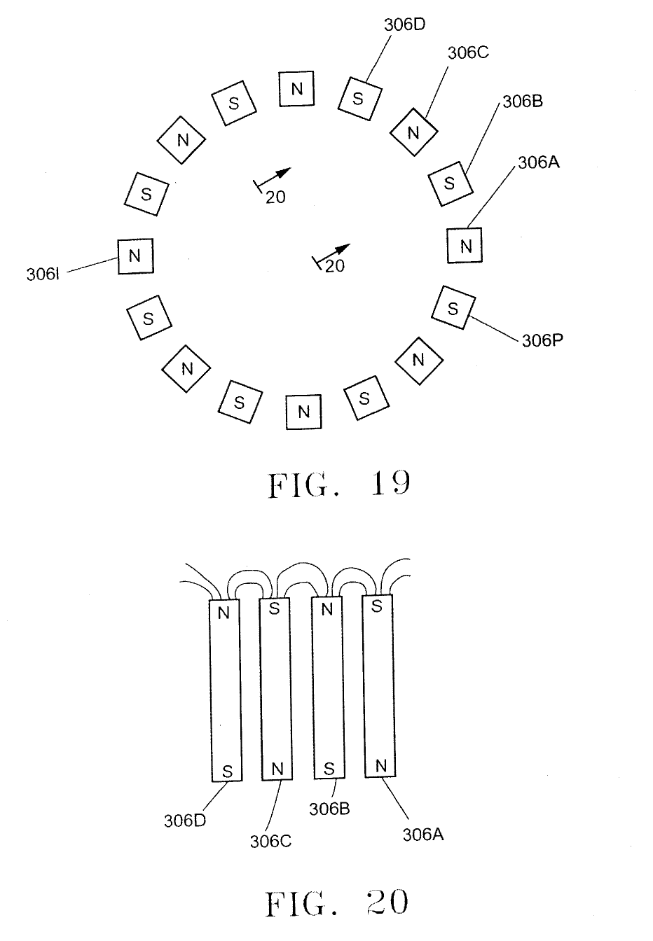

FIG. 19 shows a top view of an arrangement of bar magnets 306A-P. Each magnet 306 is oriented so that its magnetic axis is parallel to the central axis of radial symmetry of the ring defined by the magnets 306. That is, each magnet 306A-P is oriented so that its axis is perpendicular to the plane of the page and “comes out of the page” toward the viewer. This orientation can be understood from FIG. 20 which shows a side view of the magnets 306A-D generally along the line of sight 20-20 as shown in FIG. 19. The magnets 306A-P are oriented such that the adjacent ends of any two adjacent magnets 306 are of opposite polarity. The magnetic field line topology of the generated this orientation of the magnets 306A-P can be understood from the field lines illustrated in FIG. 20.

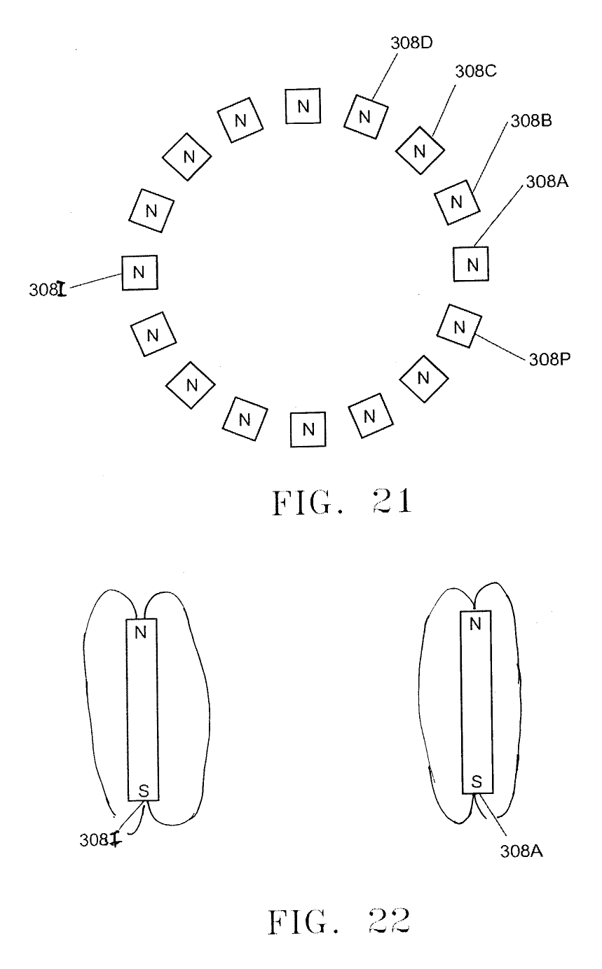

FIG. 21 shows a top view of an arrangement of bar magnets 308A-P. The orientations of the magnets 308 are similar to the orientations of the magnets 308A-P except that each magnet 308 is oriented so that the adjacent ends of any two adjacent magnets 308 are of like polarity. This orientation can be understood from FIG. 22 which shows magnets 308A and 308I in side view. The magnetic field line topology that is generated by ring of magnets 308 can be understood from the field lines generated by magnets 308A and 308I illustrated in FIG. 22.

Operation

The methods and apparatuses of the present invention are illustrated with reference to the capacitively coupled reactor 44 of FIG. 2 and the example apparatus 12 of FIG. 1. A workpiece (not shown in FIG. 2) to be processed is placed on the chuck electrode assembly 48. The control system 33 activates the vacuum system 40 which initially lowers the pressure in the interior 53 of the chamber 78 to a base pressure to assure vacuum integrity and cleanliness for the chamber 78. The control system 33 then raises the chamber pressure to a level suitable for forming a plasma and for processing a workpiece with the plasma. In order to establish a suitable pressure in the chamber interior 78, the control system 33 activates the gas supply system 24 to supply a process gas through the gas inlet line to the chamber interior 53 at a prescribed process flow rate and controls the vacuum system 40. The process gas flows through ports 84, 94 in the first electrode assembly 46 into the space 53. The particular gas or gases included in the gas supply system 24 depends on the particular plasma processing application.

The control system 33 then activates one or both of the RF power sources 34, 36 to provide an RF signal to one or both electrodes 46, 48 at selected frequencies. The control system 33 is capable of independently controlling the RF power sources 34, 36 to adjust the characteristics of the signal sent to the electrodes 46, 48 such as, for example, the frequency, waveform, and/or amplitude of the signal. One or both of the power sources 34, 36 may be operated to send appropriate signals to one or both electrodes 46, 48 to convert the low-pressure process gas to a plasma.

In order to improve the performance of the example reactor 44, or, more generally, of a plasma processing device (such as a capacitively coupled reactor, a TCP reactor or an ICP reactor) having one or more electrodes that are driven at one or more frequencies, one or more magnet assemblies may be mounted within the interior of the chamber 78. In the example reactor 44, a magnet assembly 86 is rotatably mounted within the first electrode assembly 46. For example, the control system 33 can be programmed and operated to control the rotational movement (e.g., the speed, direction and/or rate of speed change) of each magnet assembly by controlling the fluid flow from the cooling system through the passageway 75 to impose one or more rotating magnetic fields on the plasma. The cooling fluid which rotates the magnet assembly 50 simultaneously cools the magnets 52A-P to keep them within their operating temperature range. In this instance, the rate and direction of rotation of the magnet assembly 50 can be controlled by controlling the rate and direction of the fluid flow throughout the entire plasma processing apparatus or, alternatively, by controlling the rate and direction of the fluid flow through the passageway 75 only. Local control of the fluid flow can be accomplished, for example, by providing appropriate valving in the cooling system 38. Alternately, the control system 33 can be programmed and operated to control the rotational movement (e.g., the speed, direction and/or rate of speed change) of each magnet assembly by controlling a motor.

Placing a magnet assembly within a reaction chamber positions the magnets relatively close to the plasma processing space and to the plasma supported therein. In this illustrative embodiment, for example, placing the magnet assembly 50 within (or, alternatively, above or below) the first electrode assembly 46 positions the magnets 52A-P relatively close to the plasma in the top of the processing space in particular. Thus, the magnet assembly 50 may be particularly useful to alter or control the condition of the plasma in the vicinity of the first electrode assembly 46. The magnets 52A-P can be arranged so that the magnetic field emanating therefrom increases the density and/or uniformity of the plasma, particularly in the region of the processing space 53 that is immediately adjacent the first electrode assembly 46. A magnetic field topology may also be imposed on the plasma to reduce plasma wall loss. Increasing the plasma uniformity increases the process uniformity both for a single substrate and also increases process uniformity among a plurality of substrates processed in succession by the apparatus 44.

The magnets 52A-I of the magnet assembly 50 can be arranged and oriented in a great number of ways, including any of the ways shown in any of the examples illustrated in FIGS. 15-22. The magnets 52 can impose any of a number of magnetic field topologies on the plasma including, for example, a bucket field topology or a cross field topology. Because the magnets 52A-P of the magnet assembly 50 are relatively close to the plasma processing space 53, the magnets 52A-P may be subjected to a high degree of heat during processing. The magnets 52A-P can each be of equal magnetic strength to one another or can be of unequal strengths to one another. The array of magnets 52A-P can be arranged and oriented as shown in FIG. 15, for example, to impose a magnetic field on the plasma that is generally perpendicular to the electric field lines generated by the electrode assemblies 46, 48. Rotating the magnet assembly 50 can help compensate for ExB drift. ExB drift can occur if a homogeneous field crosses a plasma chamber 14 parallel to the workpiece while an electric field perpendicular to the workpiece is present in the chamber. The vector product of these magnetic fields is parallel to the workpiece and perpendicular to both sets of field lines. This results in having the electrons directed in the direction of the vector product (i.e., the “preferred” direction) which causes the plasma to be denser in one area (or “corner”) of the plasma chamber. This results in a nonuniformity of the processing of the workpiece, which is undesirable. To correct for this ExB drift, the magnetic field topology is rotated. If the magnetic field topology is uniform, however, rotating the field merely causes the “hot spot” (area of relatively high electron density) to rotate around the periphery of the plasma. To correct for this effect, the field lines of the magnetic field topology are curved which causes the electrons to “fan out” sufficiently to remove the hot spot.

The magnets 136 of the magnet assembly 110 of the processing assembly 111 may be arranged and oriented as shown in any of the FIGS. 15-22. Thus, the magnets 136 in the magnet holding structure 138 can be oriented so that its magnetic axis is parallel to the electric field lines between the first and second electrodes or perpendicular to the electric field lines. The magnets 136 can be arrangement to provide a bucket field topology (see FIG. 16, for example) which forms a magnetic “bucket” around the processing space 16. This topology produces arcuate lobes of magnetic field lines that extend toward the center of the processing region. These lobes tend to concentrate the plasma in the center of the processing region. This has a number of benefits including, for example, tending to reduce the number of plasma particles striking the surfaces of the reactor 111 and increasing plasma density by confining it to a smaller volume of space. The greater the plasma density, the faster the rate of etching or deposition, for example. Faster processing of the workpiece increases commercial productivity during, for example, semiconductor fabrication.

The lobe length can be increased by arranging the magnets in groups of two, groups of three, and so on in successive embodiments. That is, when the magnets 136 are operated in groups of two, or groups of three and so on to produce a bucket field topology, the poles magnets 136 are arranged to produce a N-N-S-S, or N-N-N-S-S-S, etc. arrangement. Generally lobe size can be The longer the lobes of the bucket field topology, the more the plasma is “squeezed” into the center of the plasma chamber 14, thereby raising plasma density and reaction rate.

The magnets 188 of the magnet assembly 160 mounted in the chuck electrode assembly 154 of the reactor 150 (see FIGS. 8-9, for example) may be arranged and oriented as shown in any of the FIGS. 15-22. The magnets 136 can used to increase plasma density and/or plasma uniformity in the vicinity of the workpiece. Similarly, the magnets 232 of the magnet assembly 210 (see FIGS. 10-12) can be arranged and oriented as shown in any of the FIGS. 15-22.

The structure and operation of each plasma processing apparatus is illustrative of one or more of the principles of the invention, and is not intended to limit the scope of the invention. Many other embodiments are contemplated. For example, an apparatus can be constructed that includes one or more independently rotated magnetic assemblies mounted within the interior of or on or about the exterior of any of the electrodes (such as the chuck electrode or the plasma generating electrode) and/or any of the insulators in the chamber. Thus, one or more magnet assemblies may be mounted may be mounted in at least one of an interior passageway within a chuck electrode assembly, a passageway mounted in structure surrounding the chuck electrode assembly, an passageway within the plasma generating electrode assembly, a passageway mounted in or formed in structure surrounding the plasma generating electrode assembly, a passageway within the interior of the insulator structure, and a passageway mounted in structure coupled to the insulator structure, or in any combination thereof.

Alternatively, an apparatus can be constructed that includes in addition to one or more magnet assemblies mounted on the interior of the reaction chamber as illustrated above, an additional apparatus that is mounted on or about the exterior of the reaction chamber (i.e., outside the walls defining the reaction chamber). Each optional externally mounted apparatus can be operated to impose one or more magnetic field topologies on the plasma during the entire or, alternatively, during selected portions of, a plasma processing operation. An external apparatus may be comprised of an array of permanent magnets that are rotated about the exterior of the chamber mechanically, or, alternatively, an external apparatus may be comprised of an array of electromagnets that are operated to impose one or more stationary or rotating magnet fields on the plasma by controlling a current in each electromagnet. Examples of externally mounted assemblies comprised of arrays of electromagnets that can be used in conjunction with one or more of the magnet assemblies described herein are described in commonly assigned U.S. Ser. No. 60/318,890 filed Sep. 14, 2001, which is hereby incorporated by reference herein in its entirety.

The magnets of each magnet assembly can have other orientations and arrangements than the ones illustrated. Each magnet assembly can be rotated by mechanism other than fluid flow. The rotational speed and direction of each magnet assembly can be constant during a plasma processing operation or can be varied.

Localized nonuniformities can occur in a plasma for a number of known reasons including, for example, because of nonuniform gas injection, nonuniform RF excitation fields being applied to the plasma, nonuniform pumping within the plasma chamber, and so on. Because each magnet assembly is positioned within the chamber and relatively close to the plasma processing space, the magnets can be positioned close to the plasma regions in the plasma where the nonuniformity occurs. This positioning provides increased control over the condition of the plasma.

It will be understood that while the electrodes of a plasma chamber were described as each being driven by an associated RF source, this does not imply that each electrode has to be driven by the associated RF source. Thus, for example, it is possible for one or the other of the pair of electrodes 18, 20 of the apparatus 10 to be constantly at ground level or at any other static (i.e., unchanging) voltage level during processing.

The many features and advantages of the present invention are apparent from the detailed specification and thus, it is intended by the appended claims to cover all such features and advantages of the described method which follow in the true spirit and scope of the invention. Further, since numerous modifications and changes will readily occur to those of ordinary skill in the art, it is not desired to limit the invention to the exact construction and operation illustrated and described. Moreover, the method and apparatus of the present invention, like related apparatus and methods used in the semiconductor arts that are complex in nature, are often best practiced by empirically determining the appropriate values of the operating parameters, or by conducting computer simulations to arrive at best design for a given application. Accordingly, all suitable modifications and equivalents should be considered as falling within the spirit and scope of the invention.

What is claimed is:

1. An apparatus for processing a workpiece with a plasma, said apparatus comprising:
a plasma chamber having an interior processing space;
a plasma generating assembly coupled to said chamber; and
a magnet assembly having a plurality of magnets and being constructed and arranged to hold the plurality of magnets in a predetermined configuration, said magnet assembly being rotatably mounted within said chamber so that the plurality of magnets are positioned to impose a magnetic field on a plasma within the processing space.

2. An apparatus according to claim 1, further comprising a cooling system operable to supply a cooling fluid to said plasma generating assembly.

3. An apparatus according to claim 2, wherein said cooling system is operatively connected to said magnet assembly so that cooling fluid from the cooling system cools the magnet assembly during processing.

4. An apparatus according to claim 3, wherein said cooling system is operatively connected to said magnet assembly such that movement of cooling fluid provides the energy to power the rotational movement of said magnet assembly and said plurality of magnets therein.

5. An apparatus according to claim 4, wherein said magnet assembly is mounted within a fluid passageway, said fluid passageway being in fluid communication with said cooling system so that cooling fluid can flow through said fluid passageway, said magnet assembly being constructed and arranged such that fluid flowing through said fluid passageway powers the rotational movement of said magnet assembly.

6. An apparatus according to claim 1, wherein said plasma generating assembly includes a chuck electrode assembly mounted within said chamber, said chuck electrode assembly being configured to support the workpiece during processing, said magnet assembly being rotatably mounted within said chuck electrode assembly.

7. An apparatus according to claim 6, wherein said chuck electrode assembly includes at least one fluid passageway, each passageway being in fluid communication with a cooling system so that cooling fluid can flow through each said fluid passageway.

8. An apparatus according to claim 7, wherein said magnet assembly includes a magnet holding structure constructed and arranged to hold said plurality of magnets in the predetermined configuration thereof, said magnet holding structure including a plurality of blades constructed and arranged to engage the flowing cooling fluid.

9. An apparatus according to claim 8, wherein said magnet holding structure is constructed of a material comprising at least one of a non-magnetic metal material and a plastic material.

10. An apparatus according to claim 1, wherein said plasma generating assembly includes a chuck electrode assembly mounted within said chamber, said chuck electrode assembly being configured to support the workpiece during processing, said magnet assembly being rotatably mounted about an exterior portion of said chuck electrode assembly.

11. An apparatus according to claim 10, wherein said chuck electrode assembly includes a support surface for supporting the workpiece, said apparatus further comprising a housing mounted around said exterior portion of the chuck electrode assembly such that said housing surrounds said support surface, said housing being constructed of a material suitable to reduce or eliminate edge effects on the workpiece during plasma processing, said housing having an interior passageway and said magnet assembly being rotatably mounted within said interior passageway.

12. An apparatus according to claim 11, wherein said interior passageway of said housing is in fluid communication with a cooling system so that cooling fluid can flow through said interior passageway, said magnet assembly being constructed and arranged such that fluid flowing through said interior passageway powers the rotational movement of said magnet assembly.

13. An apparatus according to claim 1, wherein said plasma generating assembly includes a chuck electrode assembly and a second electrode assembly, and a power source being coupled to at least one of the electrode assemblies, said chuck electrode assembly and said second electrode assembly each being mounted within said chamber in spaced relation to one another and on opposite sides of the processing space.

14. An apparatus according to claim 13, wherein said second electrode assembly includes at least one fluid passageway, each passageway being in fluid communication with a cooling system so that cooling fluid can flow through each said fluid passageway, said magnet assembly being rotatably mounted within a fluid passageway and being constructed and arranged such that fluid flowing through said fluid passageway cools said magnet assembly and powers the rotational movement of said magnet assembly.

15. An apparatus according to claim 14, wherein said magnet assembly includes a magnet holding structure constructed and arranged to hold said plurality of magnets in the predetermined configuration thereof, said magnet holding structure including a plurality of blades constructed and arranged to engage the flowing cooling fluid.

16. An apparatus according to claim 15, wherein said magnet holding structure is constructed of a material comprising at least one of a non-magnetic metal material and a plastic material.

17. An apparatus according to claim 13, further comprising an insulator structure mounted between said chuck electrode assembly and said plasma generating electrode assembly and in surrounding relation to said processing space, said insulator structure including a fluid passageway, said passageway being in fluid communication with a cooling system so that cooling fluid can flow through said fluid passageway, said magnet assembly being rotatably mounted within said fluid passageway and being constructed and arranged such that fluid flowing through said fluid passageway cools said magnet assembly and powers the rotational movement of said magnet assembly.

18. An apparatus according to claim 17, wherein said magnet assembly includes a magnet holding structure constructed and arranged to hold said plurality of magnets in the predetermined configuration thereof, said magnet holding structure including a plurality of blades constructed and arranged to engage the flowing cooling fluid.

19. An apparatus according to claim 18, wherein said magnet holding structure is constructed of a material comprises at least one of a non-magnetic metal material and a plastic material.

20. An apparatus according to claim 1, wherein said plasma generating assembly includes a chuck electrode assembly and a plasma generating coil structure, said magnet assembly being rotatably mounted between said chuck electrode assembly and said plasma generating coil structure and in surrounding relation to said processing space.

21. An apparatus according to claim 20, further comprising a housing mounted within the interior of said chamber in surrounding relation to said processing space, said housing having an interior passageway, said magnet assembly being mounted within said fluid passageway and said fluid passageway being in fluid communication with a cooling system so that cooling fluid can flow through said fluid passageway, said magnet assembly being constructed and arranged such that fluid flowing through said fluid passageway powers the rotational movement of said magnet assembly.

22. An apparatus according to claim 21, wherein said magnet assembly includes a magnet holding structure constructed and arranged to hold said plurality of magnets in the predetermined configuration thereof, said magnet holding structure including a plurality of blades constructed and arranged to engage the flowing cooling fluid.

23. An apparatus according to claim 22, wherein said magnet holding structure is constructed of a material comprising at least one of a non-magnetic metal material and a plastic material.

24. An apparatus according to claim 1, wherein the magnet assembly includes a magnet holding structure constructed and arranged to releasably hold the magnets so that each magnetic can be released from the magnet holding structure, repositioned with respect to the magnet holding structure and then releasably held in a new position of adjustment to provide the magnets with a new predetermined configuration to change the topology of the magnetic field lines produced by the plurality of magnets.

25. An apparatus according to claim 24, said plasma generating assembly comprising a chuck electrode assembly and a plasma generating electrode assembly, and at least one power source being coupled to at least one of said electrode assemblies, and further comprising an insulator structure mounted within said chamber and between said electrode assemblies in surrounding relation to the plasma processing space, the magnet assembly being mounted in at least one of an interior passageway within the chuck electrode assembly, a passageway mounted in structure surrounding the chuck electrode assembly, an interior passageway within the plasma generating electrode assembly, a passageway mounted in structure surrounding the plasma generating electrode assembly, a passageway within the interior of the insulator structure, and a passageway mounted in structure coupled to the insulator structure.

26. An apparatus according to claim 25, wherein each said magnetic is a permanent bar-shaped magnet.

27. An apparatus according to claim 25, wherein said passageway in which said magnet assembly is mounted is in fluid communication with a cooling system so that cooling fluid can flow through said fluid passageway, said magnet assembly being constructed and arranged such that fluid flowing through said fluid passageway cools said magnet assembly and powers the rotational movement of said magnet assembly.

28. An apparatus according to claim 25, wherein said magnets are arranged in a ring.

29. An apparatus according to claim 28, wherein the magnets are of equal magnetic strength to one another and are equally circumferentially spaced from one another about said ring.

30. An apparatus according to claim 28, wherein each magnet is oriented such that the axis of each magnet is perpendicular to an imaginary axis extending between said electrode assemblies.

31. An apparatus according to claim 28, wherein each magnet is oriented such that the axis of each magnet is parallel to an imaginary axis extending between the electrode assemblies.

32. An apparatus according to claim 27, wherein said magnet assembly includes a ring-shaped or disk shaped magnet holding structure constructed and arranged to hold said plurality of magnets in the predetermined configuration thereof, said magnet holding structure including a plurality of blades constructed and arranged to engage the flowing cooling fluid to facilitate power transfer from the flowing fluid to the magnet assembly to power the rotation of the magnet assembly and/or to facilitate the transfer of heat from said plurality of magnets to the cooling fluid.

33. An apparatus according to claim 32, wherein said blades are equally circumferentially spaced about said magnet holding structure.

34. An apparatus according to claim 32, wherein each said blade is straight.

35. An apparatus according to claim 32, wherein each said blade includes a curved portion.

36. An apparatus according to claim 1, further comprising an exterior magnet assembly said exterior magnet assembly being mounted about the exterior of said chamber and operable to impose one or more magnetic fields on a plasma within the processing space.

37. The apparatus according to claim 1, further comprising a cooling system operable to supply a cooling fluid to said plasma generating assembly and operable to supply a cooling fluid to said magnet assembly; and
a control system coupled to said plasma generating assembly, said magnet assembly, and said cooling system.

38. The apparatus according to claim 37, further comprising a gas supply system communicated to said chamber and operable to supply one or more gasses to said processing space; and
a vacuum system communicated to said chamber and operable to remove gas therefrom.

39. A method for processing a workpiece with a plasma, said method comprising:
positioning said workpiece in an interior processing space of a plasma chamber;
creating a plasma in said interior processing space using a plasma generating assembly coupled to said chamber; and
adjusting said plasma using a magnet assembly having a plurality of magnets arranged in a predetermined configuration, said magnet assembly being rotatably mounted within said chamber so that the plurality of magnets are positioned to adjust said plasma by imposing an adjustable magnetic field on said plasma within said processing space.
